(19) United States
(12) Patent Application Publication
(10) Pub. No.: US 2024/0404727 A1
(43) Pub. Date: Dec. 5, 2024

(54) FLEXIBLE FLAT CABLE

(71) Applicant: SAMSUNG ELECTRONICS CO., LTD., Suwon-si (KR)

(72) Inventors: Sumin KIM, Suwon-si (KR); Joonmok HAN, Suwon-si (KR)

(73) Assignee: SAMSUNG ELECTRONICS CO., LTD., Suwon-si (KR)

(21) Appl. No.: 18/658,706

(22) Filed: May 8, 2024

Related U.S. Application Data
(63) Continuation of application No. PCT/KR2024/005259, filed on Apr. 18, 2024.

(30) Foreign Application Priority Data
Jun. 2, 2023 (KR) 10-2023-0071851

(51) Int. Cl. H01B 7/08

(52) U.S. Cl. CPC H01B 7/0861; H01B 7/0846

(57) ABSTRACT

A flexible flat cable includes a base film extending in a first direction and having a first length, a conductive wire portion on a first surface of the base film and extending in the first direction, a cover film on the conductive wire portion, extending in the first direction and exposing a part of the conductive wire portion, the cover film having a second length which is less than the first length and a first conductive tape comprising a first tape area on a surface of the cover film and extending in the first direction and a second tape area folded at a certain angle from the first tape area and having a third length.

### CROSS-REFERENCE TO RELATED APPLICATIONS

This application is a continuation of International Application No. PCT/KR2024/005259, filed on Apr. 18, 2024, which is based on and claims priority to Korean Patent Application No. 10-2023-0071851, filed on Jun. 2, 2023, in the Korean Intellectual Property Office, the disclosures of which are incorporated by reference herein in their entireties.

### BACKGROUND

### 1. Field

The disclosure relates to a flexible flat cable, and more particularly, to a flexible flat cable with an improved electromagnetic interference (EMI) shielding function.

### 2. Description of the Related Art

Recently, in the electronics industry, it has become important to improve the integration of semiconductor-related devices and minimize electrical devices and components thereof. In particular, the use of flexible flat cables for signal transmission between various electronic components is increasing due to their flexible characteristics, and the need for flexible flat cables that may be applied to more complex and narrow spaces is increasing.

Electronic components constituting electronic devices connected by flexible flat cables are also becoming highly integrated, and signal processing speeds are also increasing. Noise in the form of electromagnet waves occurs while electronic components perform signal processing. Noise occurring from highly integrated electronic components is a major cause of malfunction or inefficient operation of adjacent electronic components.

EMI shielding may refer to a technology that ensures normal operation of electronic components and protects the electronic components by blocking noise occurring from other electronic components from being transmitted to the outside. For example, noise occurring from an integrated circuit (IC) chip may be prevented from being transmitted to other electronic components (e.g., IC and antenna) or electrical wirings by using EMI shielding.

### SUMMARY

Additional aspects will be set forth in part in the description which follows and, in part, will be apparent from the description, or may be learned by practice of the presented embodiments.

According to an aspect of the disclosure, a flexible flat cable includes a base film extending in a first direction and having a first length, a conductive wire portion on a first surface of the base film and extending in the first direction, a cover film on the conductive wire portion, extending in the first direction and exposing a part of the conductive wire portion, the cover film having a second length which is less than the first length, and a first conductive tape comprising a first tape area on a surface of the cover film and extending in the first direction and a second tape area folded at a certain angle from the first tape area and having a third length.

The flexible flat cable may further include a connecting member through which the part of the conductive wire portion is exposed between one end of the cover film and one end of the base film, and the second tape area may be folded at the one end of the cover film where the connecting member is located.

A length of the second tape area may be in a range of 3 cm to 10 cm.

The first conductive tape may include a conductive material layer extending in the first direction, and a protective layer on a surface of the conductive material layer.

The conductive material layer may include at least one of aluminum, an aluminum alloy, copper, silver, or gold.

A first surface of the conductive material layer located in the first tape area may face the cover film, and a second surface of the conductive material layer in the second tape area may be exposed to an outside.

Each of the base film and the cover film may include an insulating material.

The second tape area may contact a first ground portion provided on a first component and may contact a second ground portion provided on a third component.

The first component may include a printed circuit board, and the third component may include at least one of a frame portion, a heat dissipation portion, a metal case, or a surface-mounted device gasket.

The flexible flat cable may further include a second conductive tape comprising a third tape area on a second surface of the base film so as to overlap the base film along the first direction and a fourth tape area extending from the third tape area in the first direction so as not to overlap the base film.

A length of the third tape area may be in a range of 3 cm to 10 cm.

The second conductive tape may include a conductive material layer extending in the first direction, and a protective layer on a surface of the conductive material layer.

A first surface of the conductive material layer in the third tape area may face the base film, and a second surface of the conductive material layer in the fourth tape area may be exposed to an outside.

The flexible flat cable may further include a support tape on a second surface of the base film and comprising a material having an elastic force.

The conductive wire portion may include a plurality of conductive wire portions, the plurality of conductive wire portions may include a first conductive wire portion configured to transmit a signal and a second conductive wire portion configured to transmit an operating voltage, and the plurality of conductive wire portions may not comprise a ground conductive wire portion.

The flexible flat cable may further include a connecting member through which the part of the conductive wire portion is exposed between one end of the cover film and one end of the base film, the second tape area may be folded at the one end of the cover film where the connecting member is located.

A length of the second tape area may be in a range of 3 cm to 10 cm.

The first conductive tape may include a conductive material layer extending in the first direction, and a protective layer on a surface of the conductive material layer.

The conductive material layer may include at least one of aluminum, an aluminum alloy, copper, silver, or gold.

A first surface of the conductive material layer located in the first tape area may face the cover film, and a second surface of the conductive material layer in the second tape area may be exposed to an outside.

### BRIEF DESCRIPTION OF THE DRAWINGS

FIG. 1 is an exploded perspective view illustrating a display apparatus, according to an embodiment of the disclosure.

FIG. 2 is a perspective view illustrating a flexible flat cable, according to an embodiment of the disclosure.

FIG. 3 is an exploded perspective view illustrating a flexible flat cable, according to an embodiment of the disclosure.

FIG. 4 is a side view illustrating a conductive tape, according to an embodiment of the disclosure.

FIG. 5 is a cross-sectional view illustrating a flexible flat cable, according to an embodiment of the disclosure.

FIG. 6 is a perspective view illustrating a process in which a flexible flat cable is connected to a first component, according to an embodiment of the disclosure.

FIG. 7 is a schematic cross-sectional view illustrating a first component, a third component, and a flexible flat cable in a state where the flexible flat cable is connected to the first component, according to an embodiment of the disclosure.

FIG. 8 is an exploded perspective view illustrating a flexible flat cable, according to an embodiment of the disclosure.

FIG. 9 is a cross-sectional view illustrating a flexible flat cable, according to an embodiment of the disclosure.

FIG. 10 is an exploded perspective view illustrating a flexible flat cable, according to an embodiment of the disclosure.

FIG. 11 is a cross-sectional view illustrating a flexible flat cable, according to an embodiment of the disclosure.

### DETAILED DESCRIPTION

Hereinafter, a configuration and an operation of the disclosure will be described in detail with reference to the accompanying drawings.

The terms used herein will be briefly described, and the disclosure will be described in detail.

The terms used herein are general terms currently widely used in the art in consideration of functions in the disclosure, but the terms may vary according to the intention of one of ordinary skill in the art, precedents, or new technology in the art. Also, some of the terms used herein may be arbitrarily chosen by the present applicant, and in this case, these terms are defined in detail below. Accordingly, the specific terms used herein should be defined based on the unique meanings thereof and the whole context of the disclosure.

It will be understood that when a certain part “includes” a certain component, the part does not exclude another component but may further include another component, unless the context clearly dictates otherwise.

It will be understood that although the terms “first,” “second,” etc. may be used herein to describe various components, these components should not be limited by these terms. These terms are only used to distinguish one component from another.

The disclosure will now be described more fully with reference to the accompanying drawings for one of ordinary skill in the art to be able to perform the disclosure without any difficulty. However, the disclosure may be embodied in many different forms and is not limited to the embodiments set forth herein. For clarity, portions irrelevant to the descriptions of the disclosure are omitted in the drawings, and like components are denoted by like reference numerals throughout the specification.

The terms “upper side”, “lower side”, and “front-back direction” used herein are defined based on the drawings, and a shape and a position of each element are not limited by these terms.

Hereinafter, an embodiment of the disclosure will be described in detail with reference to the accompanying drawings.

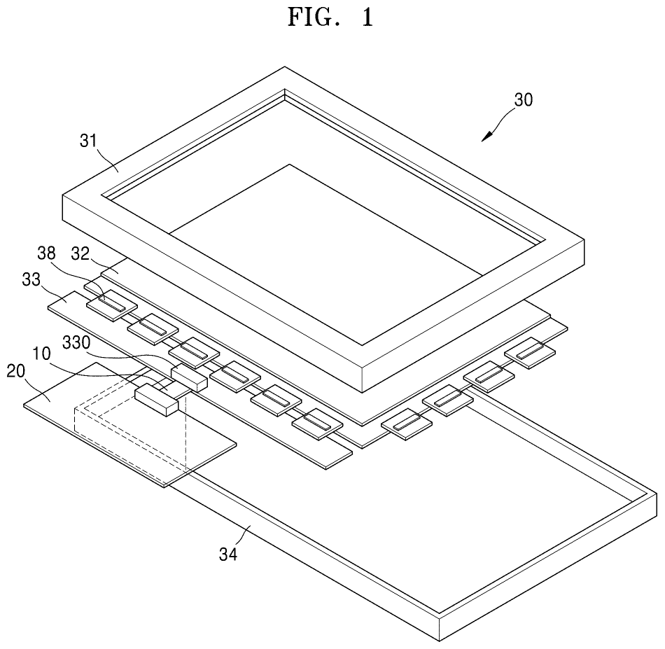

FIG. 1 is an exploded perspective view illustrating a display apparatus, according to an embodiment of the disclosure.

A flexible flat cable 10 according to an example may be located between a first component 33 and a second component 20 and may connect the first component 33 to the second component 20. In this case, a third component 34 may be located between the first component 33 and the second component 20 and may contact a part of the flexible flat cable 10.

For example, referring to FIG. 1, a display apparatus 30 according to an example may include an upper frame 31, a display module 32, the first component 33, the second component 20, the third component 34, and a driver 38. The display module 32 according to an example may display an image. The driver 38 is located on one side of the display module 32 to drive a liquid crystal panel. In this case, the first component 33 is a first printed circuit board, the first component 33 provides driving and control signals to the display module 32, and the second component 20 is a second printed circuit board. The second component 20 may be connected to the first component 33 through the first flat cable 10. In this case, the third component 34 is a lower frame and may be located between the first component 33 and the second component 20 to be connected by using the flexible flat cable 10. The third component 34 may contact a part of the flexible flat cable 10.

Hereinafter, for convenience of explanation, the first component 33 and the second component 20 to be connected by using the flexible flat cable 10 according to an example will be described respectively as a first printed circuit board and a second printed circuit board, and the third component 34 will be described as a lower frame located between the first printed circuit board and the second printed circuit board.

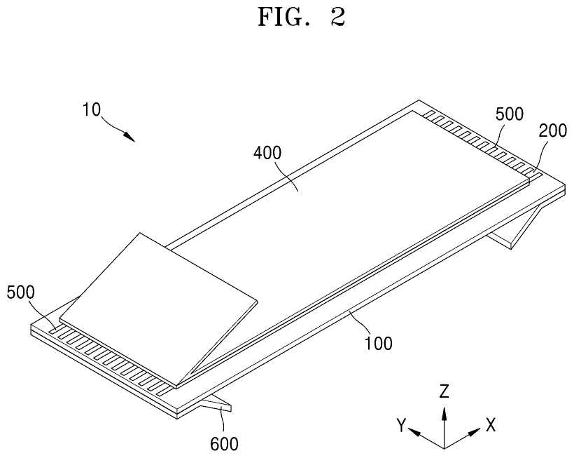

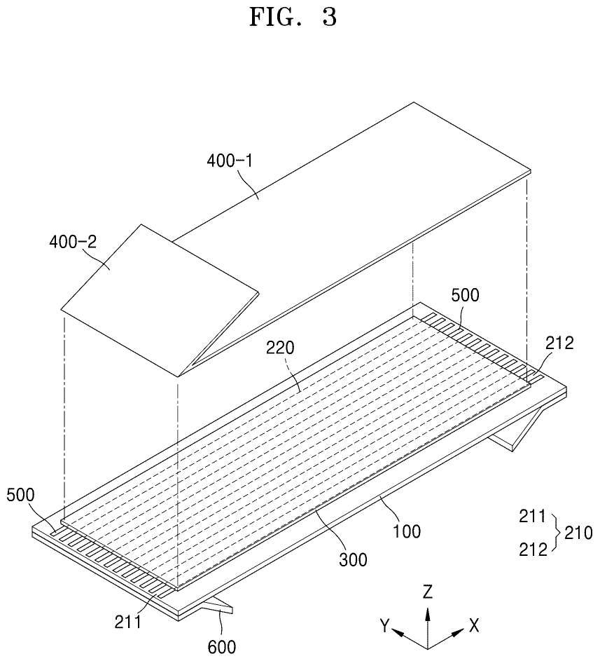

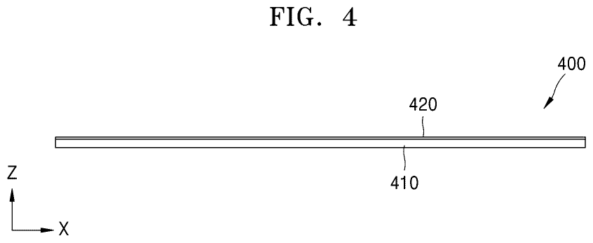

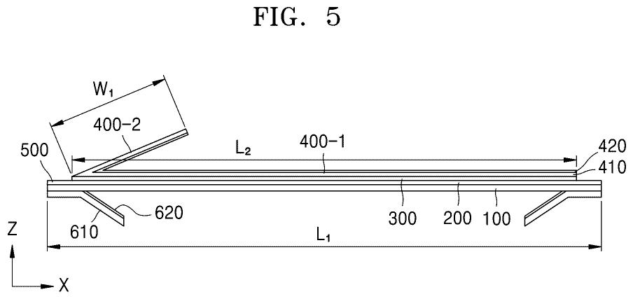

FIG. 2 is a perspective view illustrating a flexible flat cable, according to an embodiment of the disclosure. FIG. 3 is an exploded perspective view illustrating a flexible flat cable, according to an embodiment of the disclosure. FIG. 4 is a side view illustrating a conductive tape, according to an embodiment of the disclosure. FIG. 5 is a cross-sectional view illustrating a flexible flat cable, according to an embodiment of the disclosure.

Referring to FIGS. 2 to 5, the flexible flat cable 10 according to an example may include a base film 100, a conductive wire portion 200, a cover film 300, a first conductive tape 400, a connecting member 500, and a support tape 600.

The base film 100 may extend to have a length and a width set during a manufacturing process. According to an example, when a direction in which the base film 100 extends is defined as a first direction (X-direction), the base film 100 may be provided in a film shape extending to a first length along the first direction (X-direction). For example, the base film 100 may include an insulating material. For example, the base film 100 may be formed of heat-resistant polyester, polyester, or a combination thereof. For example, the base film 100 be formed of a heat-adhesive synthetic resin having insulation, heat resistance, flexibility, and resilience as well as mechanical strength such as tensile strength. For example, the base film 100 may be selected from synthetic resins including nylon, acetate, and polyester-based resins. However, the disclosure is not limited thereto, and the base film 100 may include any material that may ensure bendability of the flexible flat cable 10.

The conductive wire portion 200 may be located on one surface of the base film 100. For example, the conductive wire portion 200 may extend along the first direction (X-direction) in which the base film 100 extends. Also, a plurality of conductive wire portions 200 may be provided. According to an example, when a plurality of conductive wire portions 200 are provided, the plurality of conductive wire portions 200 may be arranged at certain intervals to be spaced apart from each other along a width direction (Y-direction) of the base film 100. The width direction or second direction (Y-direction) may be perpendicular to the first direction (X-direction). The conductive wire portions 200 are located adjacent to each other in the width direction (Y-direction), but may be arranged parallel to each other with a certain interval therebetween so as not to contact each other.

When a plurality of conductive wire portions 200 are provided, each of the plurality of conductive wire portions 200 may transmit a different signal or voltage. For example, the plurality of conductive wire portions 200 may include a conductive wire portion that transmits a signal, a conductive wire portion that transmits an operating voltage, and a conductive wire portion that transmits current.

Because the conductive wire portion 200 is an element through which an electrical signal or current is transmitted, the conductive wire portion 200 may be formed of a conductive material. For example, the conductive wire portion 200 may be formed of a conductive material such as silver, copper, nickel, cobalt, or a combination thereof. The flexible flat cable 10 may be formed by placing the conductive wire portion 200 manufactured through a separate manufacturing process on one surface of the base film 100, covering the cover film 300 described below on the base film 100, and pressing the cover film 300.

According to another example, the conductive wire portion 200 may be formed by printing conductive paste in a stripe shape on one surface of the base film 100. As the conductive paste, a composition obtained by mixing a silver filler of 50 to 70 percent by weight (wt %) and a binder of 30 to 50 wt % may be used. In addition to the silver filler, the conductive paste may be formed of any of various conductive materials such as a copper filler, a filler coated with silver on copper, copper, nickel, cobalt, or combinations thereof in various content ratios. Printing methods may include various methods such as general gravure printing, inkjet printing, offset printing, silk screen printing, and rotary screen printing.

According to an example, the conductive wire portion 200 may include terminal portions 210 located on both ends, and a wiring portion 220 located between the terminal portions 210. A plurality of terminal portions 210 may be provided and located at both ends of the base film 100. For example, a first terminal portion 211 may be located at one end of the base film 100 and a second terminal portion 212 may be located at the other end of the base film 100. A plurality of wiring portions 220 may be arranged parallel to each other in the width direction (Y-direction) of the base film 100. For example, the wiring portions 220 are located adjacent to each other in the width direction, but may be arranged parallel to each other with a certain interval therebetween so as not to contact each other. Accordingly, the conductive wire portion 200 may be located on the base film 100 in the order of the first terminal portion 211, the wiring portion 220, and the second terminal portion 212 of the conductive wire portion 200 along the first direction (X-direction).

According to an example, in order to prevent a part of the conductive wire portion 200, for example the wiring portion 220, from being exposed to the outside, the cover film 300 may be located on the conductive wire portion 200 located on one surface of the base film 100 and then laminating for bonding the cover film 300 to the base film 100 may be performed.

The cover film 300 may extend to have a set length and a width during a manufacturing process, like the base film 100. The cover film 300 may be formed to cover a part of the conductive wire portion 200, for example, the wiring portion 220, located on the base film 100 and to have a width less than that of the base film 100. For example, when the base film 100 extends to a first length L₁ along the first direction (X-direction), the cover film 300 may extend to a second length L₂, which is less than the first length L₁, along the first direction (X-direction). Accordingly, the remaining part of the conductive wire portion 200, for example, the terminal portion 210, may be exposed to the outside. The cover film 300 may be formed of heat-resistant polyester, polyester, or a combination thereof.

For example, the cover film 300 may be formed of a heat-adhesive synthetic resin having insulation, heat resistance, flexibility, and resilience as well as mechanical strength such as tensile strength. For example, the cover film 300 may be selected from among synthetic resins including nylon, acetate, and polyester-based resins. However, the disclosure is not limited thereto, and the cover film 300 may include any material that ensures bendability of the flexible flat cable 10.

According to an embodiment of the disclosure, the flexible flat cable 10 may functionally connect components mounted on an electronic device. The conductive wire portion 200 may include the wiring portion 220 located between the terminal portions 210. Components of the electronic device connected through the terminal portion 210 may be functionally connected to each other through the wiring portion 220. For example, as shown in FIG. 1, one end of the flexible flat cable 10 may be connected to the first component 33 through the first terminal portion 211, and the other end of the flexible flat cable 10 may be connected to the second component 20 through the second terminal portion 212. The wiring portion 220 may electrically connect the first component 33 to the second component 20, and may be a transmission path through a high-speed signal and/or a low-speed signal is transmitted between the first and second components 33 and 20.

According to an example, when a signal is transmitted through the wiring portion 220, electromagnetic interference (EMI) may be generated around the wiring portion 220. According to an example, the flexible flat cable 10 may include the first conductive tape 400 for shielding EMI generated around the wiring portion 220. For example, the first conductive tape 400 may be attached to at least partially surround the wiring portion 220.

The first conductive tape 400 may surround the wiring portion 220 to shield electromagnetic waves transmitted from the wiring portion 220 to the outside and noise transmitted from the outside to the wiring portion 220. The first conductive tape 400 according to an example may be provided in a thin plate shape having a certain thickness. In this case, the first conductive tape 400 may have an arbitrary thickness that may ensure bendability.

According to an embodiment of the disclosure, the first conductive tape 400 may include a conductive material layer 410 and a protective layer 420. For example, as shown in FIG. 4, the conductive material layer 410 and the protective layer 420 may be stacked to be adhered to each other. The conductive material layer 410 may extend along one direction (X-direction) and may include a conductive material. The conductive material layer 410 according to an example may include at least one of aluminum, an aluminum alloy, copper, silver, or gold. However, the disclosure is not limited thereto, and the conductive material layer 410 may include any conductive material that may ensure bendability.

The protective layer 420 may be located on one surface of the conductive material layer 410 to protect the conductive material layer 410 from external impact. According to an embodiment of the disclosure, the protective layer 420 may be stacked on a top surface of the conductive material layer 410. For example, the wiring portion 220 may be located on a bottom surface of the conductive material layer 410, and the protective layer 420 may be located on the top surface of the conductive material layer 410.

As described above, in order to shield electromagnetic waves transmitted from the wiring portion 220 to the outside and noise transmitted from the outside to the wiring portion 220, the first conductive tape 400 may surround the wiring portion 220. In order to shield electromagnetic waves transmitted from the wiring portion 220 to the outside and noise transmitted from the outside to the wiring portion 220, the conductive material layer 410 included in the first conductive tape 400 may be physically connected to a first ground portion GND1 provided on the first component 33 and a second ground portion GND2 provided on the third component 34 of FIG. 1. As the conductive material layer 410 included in the first conductive tape 400 is physically connected to the first ground portion GND1 and the second ground portion GND2 provided on the first component 33 and the third component 34 of FIG. 1, a return path may be formed to shield EMI noise.

According to an example, the first conductive tape 400 may include a 1-1 tape area 400-1 located to be adhered to one surface of the cover film 300 along the first direction (X-direction) and a 1-2 tape area 400-2 folded at a certain angle from the 1-1 tape area 400-1.

In the 1-1 tape area 400-1, one surface of the conductive material layer 410 provided in the first conductive tape 400 may face the cover film 300. In this case, the one surface of the conductive material layer 410 may be located to be adhered to one surface of the cover film 300 by using an adhesive. A length of the 1-1 tape area 400-1 along the first direction (X-direction) may correspond to the second length L₂ of the cover film 300. However, the disclosure is not limited thereto, and a length of the 1-1 tape area 400-1 along the first direction (X-direction) may be less than the second length L₂ of the cover film 300.

The 1-2 tape area 400-2 may be folded or extend at a certain angle from the 1-1 tape area 400-1 and may extend to a certain length W₁. According to an example, the 1-2 tape area 400-2 may be folded at one end of the cover film 300 on which the connecting member 500 is located. The connecting member 500 according to an example may be located in an area between one end of the cover film 300 and one end of the base film 100. In this case, the terminal portion 210 provided in the conductive wire portion 200 may be located on the connecting member 500 to be exposed to the outside.

Also, according to an example, the certain length W₁ of the 1-2 tape area 400-2 extending from the 1-1 tape area 400-1 may be 3 cm or more and 10 cm or less. However, the disclosure is not limited thereto, and the certain length W₁ may be differently determined according to structures of the first ground portion GND1 provided on the first component 33 and the second ground portion GND2 provided on the third component 34 which the 1-2 tape area 400-2 should contact.

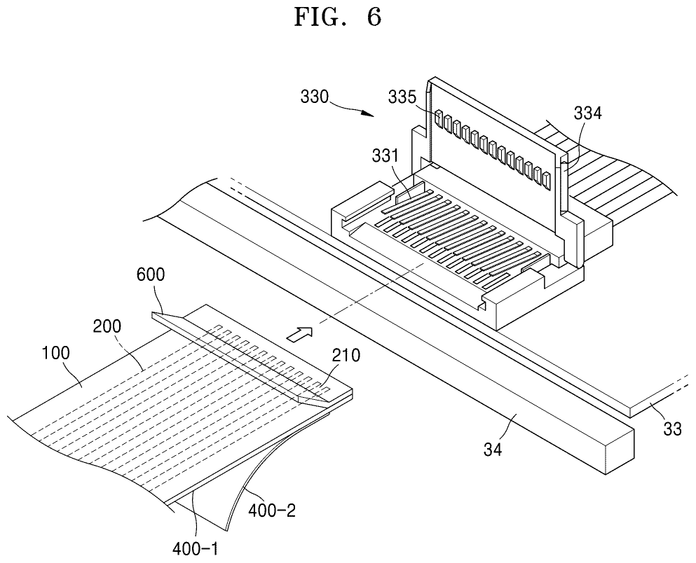

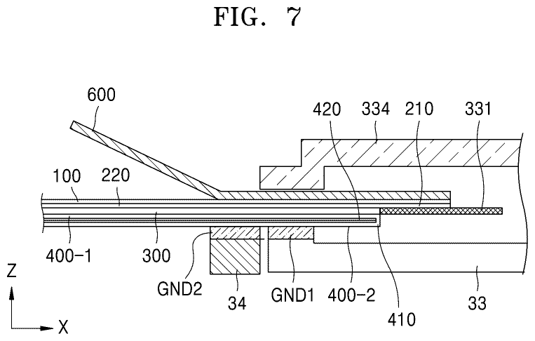

In the 1-2 tape area 400-2, one surface of the conductive material layer 410 provided in the first conductive tape 400 may be exposed to the outside. For example, when the flexible flat cable 10 is located between the first component 33 and the second component 20 to connect the first component 33 to the second component 20, one surface of the conductive material layer 410 located in the 1-2 tape area 400-2 may physically contact the first ground portion GND1 and the second ground portion GND2 provided on the first component 33 and the third component 34. As the one surface of the conductive material layer 410 located in the 1-2 tape area 400-2 is physically connected to the first ground portion GND1 and the second ground portion GND2, a return path may be formed to shield EMI noise. Physical connection of one surface of the conductive material layer 410 located in the 1-2 tape area 400-2 to the first ground portion GND1 and the second ground portion GND2 will be described below in more detail with reference to FIGS. 6 and 7.

Referring back to FIGS. 3 and 5, the support tape 600 may be located on the other surface of the base film 100, for example, a surface opposite to one surface of the base film 100 on which the cover film 300 is located. The support tape 600 according to an example may be located at a position corresponding to the connecting member 500 formed between the base film 100 and the cover film 300. For example, the support tape 600 may face the connecting member 500 with the base film 100 there between.

The support tape 600 according to an example may be formed to have the same width as the base film 100 and may be formed to have a length greater than that of the connecting member 500. Also, the support tape 600 may include a material having a certain elastic force. For example, the support tape 600 may include the same material as that of the base film 100. The support tape 600 may be adhered to a rear surface of the base film 100 by using a polyester adhesive. Alternatively, the support tape 600 may be formed in a tape shape.

According to an example, when an elastic force is applied to the flexible flat cable 10 to connect one end of the flexible flat cable 10 to the first component 33 or the second component 20, the support tape 600 may apply pressure so that one end of the flexible flat cable 10 comes into closer contact with a connector provided in the first component 33 or the second component 20.

A part of the support tape 600 according to an example may be spaced apart from the base film 100. The part of the support tape 600 spaced apart from the base film 100 may function as a handle when the flexible flat cable 10 is separated from the first component 33 or the second component 20. When the support tape 600 is formed in a tape shape, a silicone tape 620 may be attached to the part of the support tape 600 spaced apart from the base film 100. As such, when the silicone tape 620 is attached to the part of the support tape 600, the part of the support tape 600 may be prevented from being attached to the rear surface of the base film 100.

FIG. 6 is a perspective view illustrating a process in which a flexible flat cable is connected to a first component, according to an embodiment of the disclosure. FIG. 7 is a schematic cross-sectional view illustrating a first component, a third component, and a flexible flat cable in a state where the flexible flat cable is connected to the first component, according to an embodiment of the disclosure.

Referring to FIGS. 1, 6, and 7, the flexible flat cable 10 according to an example may be located between the first component 33 and the second component 20 to connect the first component 33 or the second component 20. In order for the flexible flat cable 10 to be connected to the first component 33 or the second component 20, a connector may be located on the first component 33 or the second component 20. For example, when the first component 33 includes a printed circuit board, a connector 330 may be located on one side portion of the first component 33. In this case, one end of the flexible flat cable 10 may be connected to the connector 330.

The connector 330 may include a connecting portion 331, a housing, and a cover 334. The connecting portion 331 may be formed to correspond to the terminal portion 210 provided at one end of the flexible flat cable 10. For example, when a plurality of terminal portions 210 are arranged side by side in the width direction (Y-direction) of the base film 100, the connecting portion 331 may include connection pins whose number is equal to the number of exposed terminal portions 210.

When one end of the flexible flat cable 10 is connected to the connector 330, the terminal portions 210 may be in contact with the connection pins provided in the connecting portion 331. After the terminal portions 210 contact the connecting portion 331, the cover 334 may be closed. When the cover 334 is closed, a pressing portion 335 located inside the cover 334 and the support tape 600 may press the terminal portion 210 and the connecting portion 331 which vertically overlap each other to bind the terminal portion 210 and the connecting portion 331.

The third component 34 may be an arbitrary component that is located between the first component 33 and the second component 20 to be connected by using the flexible flat cable 10 and on which the second ground portion GND2 is located or that is electrically connected to the second ground portion GND2. For example, the third component 34 may be any one of a frame portion, a heat dissipation portion, a metal case, and a surface-mounted device gasket. Hereinafter, a chassis portion forming a frame of the display apparatus 30 of FIG. 1 will be described as an example of the third component 34.

The third component 34 may be located to support the display apparatus 30. The third component 34 may be located on at least one of a front side, a rear side, or a side of the display apparatus 30. For example, the third component 34 may cover a part of a front surface or a rear surface of the display apparatus 30. Alternatively, the third component 34 may cover a side surface of the display apparatus 30. As shown in FIG. 1, the display apparatus 30 may include a printed circuit board as at least the first component 33 electrically connected to the display module 32. The printed circuit board as the first component 33 according to an example may be located adjacent to the chassis portion that is the first component 34 and may be mounted on the chassis portion.

The first ground portion GND1 and the second ground portion GND2 may be respectively located on the first component 33 and the third component 34 according to an example, or the first component 33 and the third component 34 may be respectively electrically connected to the first ground portion GND1 and the second ground portion GND2. For example, when the first component 33 is a printed circuit board, the first ground portion GND1 located on the first component 33 may be located on one surface of the printed circuit board. For example, when the connector 330 is located on one side portion of the first component 33, the first ground portion GND1 may be located under or on a front surface of the connector 330. Also, for example, when the chassis portion that is the third component 34 is formed of a conductive material, the chassis portion may be conductively bonded to the second ground portion GND2 located outside. Any of various methods such as welding or adhesion using a conductive adhesive may be used for conductive bonding.

According to an example, when one end of the flexible flat cable 10 is connected to the first component 33, the 1-2 tape area 400-2 of the first conductive tape 400, which is folded at a certain angle from the 1-1 tape area 400-1, may overlap the 1-1 tape area 400-1. Accordingly, one surface of the conductive material layer 410 provided in the first conductive tape 400 in the 1-2 tape area 400-2 may be located to exposed to the outside.

The one surface of the conductive material layer 410 located in the 1-2 tape area 400-2 which is exposed to the outside may physically contact the first ground portion GND1 and the second ground portion GND2 provided on the first component 33 and the third component 34. As the one surface of the conductive material layer 410 located in the 1-2 tape area 400-2 is physically connected to the first ground portion GND1 and the second ground portion GND2, a return path may be formed to reduce EMI noise occurring from the wiring portion 220.

Also, a conductive wire portion provided in a conventional flexible flat cable needs to include a separate ground conductive wire portion for reducing EMI noise. However, as the one surface of the conductive material layer 410 located in the 1-2 tape area 400-2 is physically connected to the first ground portion GND1 and the second ground portion GND2 to reduce EMI noise occurring from the wiring portion 220 as in an example, the number of conductive wire portions 200 may be reduced.

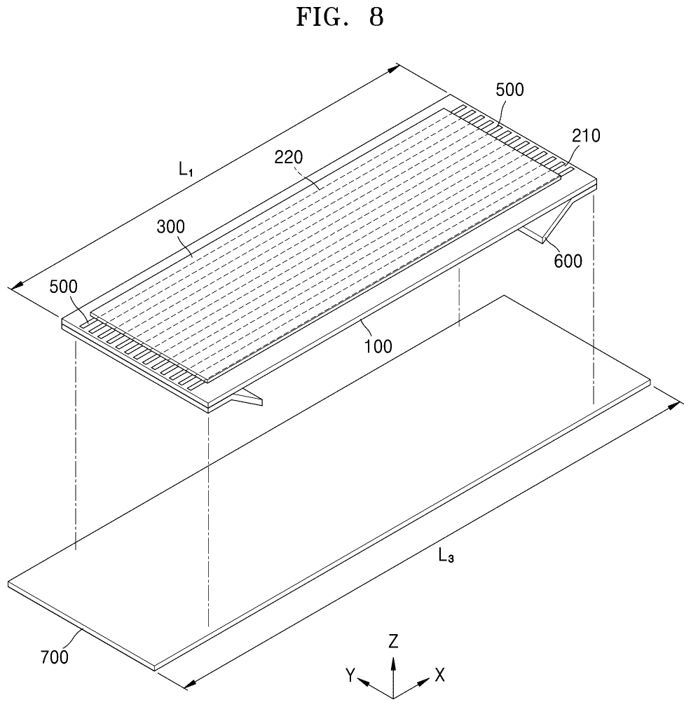

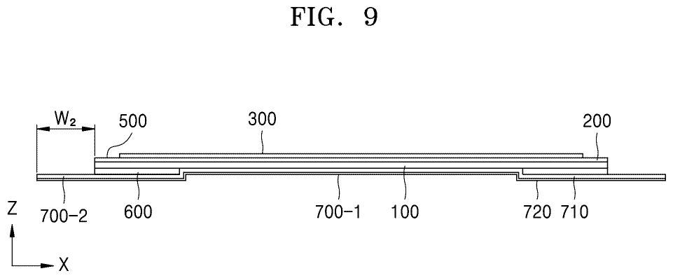

FIG. 8 is an exploded perspective view illustrating a flexible flat cable, according to an embodiment of the disclosure. FIG. 9 is a cross-sectional view illustrating a flexible flat cable, according to an embodiment of the disclosure.

Referring to FIGS. 8 and 9, the flexible flat cable 10 according to an example may include the base film 100, the conductive wire portion 200, the cover film 300, the connecting member 500, the support tape 600, and a second conductive tape 700. Elements other than the second conductive tape 700 are substantially the same as those in FIGS. 2 and 3, and thus, will not be described for convenience of explanation.

The second conductive tape 700 may surround the wiring portion 220 to shield electromagnetic waves transmitted from the wiring portion 220 to the outside and noise transmitted from the outside to the wiring portion 220. The second conductive tape 700 according to an example may be provided in a thin plate shape having a certain thickness. In this case, the second conductive tape 700 may have an arbitrary thickness that may ensure bendability. Also, the second conductive tape 700 may extend to a third length L₃ along the first direction (X-direction). In an example, when the base film 100 extends to the first length L₁ along the first direction (X-direction), the third length L₃ may exceed the first length L₁.

According to an embodiment of the disclosure, the second conductive tape 700 may include a conductive material layer 710 and a protective layer 720. The conductive material layer 710 and the protective layer 720 may be substantially the same as the conductive material layer 410 and the protective layer 420 of FIG. 4, and thus, will not be described for convenience of explanation.

According to an example, the second conductive tape 700 may include a 2-1 tape area 700-1 located to be adhered to the other surface of the base film 100 along the first direction (X-direction) and overlapping the base film 100 and a 2-2 tape area 700-2 extending from the 2-1 tape area 700-1 along the first direction (X-direction) so as not to overlap the base film 100.

One surface of the conductive material layer 710 provided in the second conductive tape 700 in the 2-1 tape area 700-1 may face the other surface of the base film 100. In this case, the one surface of the conductive material layer 710 may be located to be adhered to the other surface of the base film 100 by using an adhesive. In this case, the one surface of the conductive material layer 710 may be located to be adhered to one surface of the support tape 600. Also, in this case, the silicone tape 620 attached to a part of the support tape 600 spaced apart from the base film 100 may not be located. Accordingly, the part of the support tape 600 may be attached to a rear surface of the base film 100.

The 2-2 tape area 700-2 may extend to a certain length W₂ from the 2-1 tape area 700-1 along the first direction (X-direction). For example, the certain length W₂ of the 2-2 tape area 700-2 extending along the first direction (X-direction) may be 3 cm or more and 10 cm or less. However, the disclosure is not limited thereto, and the certain length W₂ may be differently determined according to structures of the first ground portion GND1 provided on the first component 33 and the second ground portion GND2 provided on the third component 34 which the 2-2 tape area 700-2 should contact.

One surface of the conductive material layer 710 provided in the second conductive tape 700 in the 2-2 tape area 700-2 may be exposed to the outside. For example, when the flexible flat cable 10 is located between the first component 33 and the second component 20 to connect the first component 33 to the second component 20, one surface of the conductive material layer 710 located in the 2-2 tape area 700-2 may physically contact the first ground portion GND1 and the second ground portion GND2 provided on the first component 33 and the third component 34. As the one surface of the conductive material layer 710 located in the 2-2 tape area 700-2 is physically connected to the first ground portion GND1 and the second ground portion GND2, a return path may be formed to shield EMI noise.

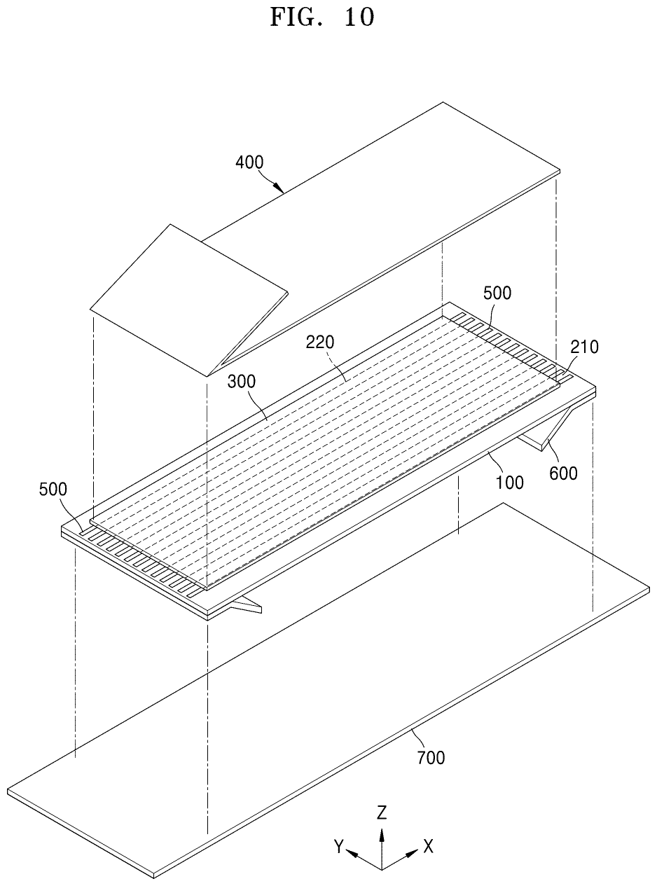

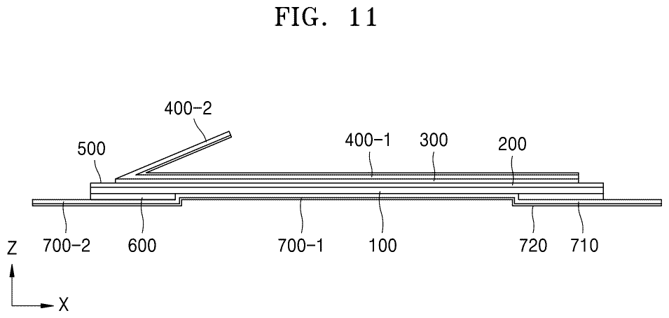

FIG. 10 is an exploded perspective view illustrating a flexible flat cable, according to an embodiment of the disclosure. FIG. 11 is a cross-sectional view illustrating a flexible flat cable, according to an embodiment of the disclosure.

According to an example, a plurality of conductive tapes for shielding EMI noise may be provided.

Referring to FIGS. 10 and 11, the flexible flat cable 10 according to an example may include the base film 100, the conductive wire portion 200, the cover film 300, the first conductive tape 400, the connecting member 500, the support tape 600, and the second conductive tape 700. In this case, the first conductive tape 400 may be located on one surface of the base film 100, and the second conductive tape 700 may be located on the other surface of the base film 100. The base film 100, the conductive wire portion 200, the cover film 300, the first conductive tape 400, the connecting member 500, the support tape 600, and the second conductive tape 700 of the flexible flat cable 10 are substantially the same as those described with reference to FIGS. 2, 3, 8, and 9, and thus, will not be described for convenience of explanation.

Reference numerals have been described in exemplary embodiments of the disclosure in order to gain an understanding of the disclosure, and specific terms have been used in order to describe the embodiments of the disclosure. However, the disclosure is not restricted to the specific terms and thus, may include all types of elements which may be generally considered by one of ordinary skill in the art.

Specific executions described in the disclosure are examples and do not limit the scope of the disclosure. Also, connections among lines of elements or connection members illustrated in the drawings have been exemplarily described for functional connections and/or physical connections. Thus, they may be expressed as various additional functional connections or physical connections in a real apparatus. Also, when there is no detailed mention such as “essential” or “importantly”, it is not an essential element for applying the disclosure. Expressions used herein such as “comprising” or “including” are used to be understood as terms for open ending of technology.

In the specification, the term “the” and designation terms similar thereto may correspond to both a singular form and a plural form. Also, when there is disclosed a range, the disclosure to which separate values belonging to the range are applied are included when there is no contrary description, which is identical to setting forth separate values forming the range, respectively. When an order of operations constituting a method according to the disclosure is clearly described or is not clearly described, the operations may be performed according to an appropriate order. The disclosure is not limited to the order of the operations. All examples or exemplary terms (e.g., etc.) have been used to describe the disclosure in detail and thus, do not restrict the scope of the disclosure as defined by the following claims. Numerous modifications and adaptations will be readily apparent to one of ordinary skill in this art without departing from the spirit and scope of the disclosure as defined by the following claims.

A flexible flat cable according to an example includes a base film extending to a first length along a first direction, a conductive wire portion located on one surface of the base film and extending along the first direction, a cover film located on the conductive wire portion and extending to a second length, which is less than the first length, along the first direction to expose a part of the conductive wire portion, and a first conductive tape including a 1-1 tape area located on one surface of the cover film and extending along the first direction and a 1-2 tape area folded at a certain angle from the 1-1 tape area and extending to a certain length along one direction.

The flexible flat cable may further include a connecting member through which the conductive wire portion is exposed between one end of the cover film and one end of the base film, wherein the 1-2 tape area is folded at the one end of the cover film where the connecting member is located.

A length of the 1-2 tape area extending along the one direction is 3 cm or more and 10 cm or less.

The first conductive tape may include a conductive material layer extending along one direction and including a conductive material, and a protective layer located on one surface of the conductive material layer.

The conductive material layer may include at least one of aluminum, an aluminum alloy, copper, silver, or gold.

One surface of the conductive material layer located in the 1-1 tape area may face the cover film, and one surface of the conductive material layer located in the 1-2 tape area may be exposed to outside.

Each of the base film and the cover film may include an insulating material.

The 1-2 tape area may contact a first ground portion provided on a first component and a second ground portion provided on a third component.

The first component may include a printed circuit board, and the third component may include at least one of a frame portion, a heat dissipation portion, a metal case, or a surface-mounted device gasket.

The flexible flat cable may further include a second conductive tape including a 2-1 tape area located on the other surface of the base film and overlapping the first base film along the first direction and a 2-2 tape area extending from the 2-1 tape area along the first direction so as not to overlap the base film.

A length of the 2-2 tape area extending along the first direction may be 3 cm or more and 10 cm or less.

The second conductive tape may include a conductive material layer extending along one direction and including a conductive material, and a protective layer located on one surface of the conductive material layer.

One surface of the conductive material layer located in the 2-1 tape area may face the base film, and one surface of the conductive material layer located in the 2-2 tape area may be exposed to outside.

The flexible flat cable may further include a support tape located on the other surface of the base film and including a material having a certain elastic force.

The conductive wire portion may include a plurality of conductive wire portions, wherein the plurality of conductive wire portions include a conductive wire portion that transmits a signal and a conductive wire portion that transmits an operating voltage, and do not include a ground conductive wire portion.

What is claimed is:

1. A flexible flat cable comprising:
a base film extending in a first direction and having a first length;
a conductive wire portion on a first surface of the base film and extending in the first direction;
a cover film on the conductive wire portion, extending in the first direction and exposing a part of the conductive wire portion, the cover film having a second length which is less than the first length; and
a first conductive tape comprising:
a first tape area on a surface of the cover film and extending in the first direction; and
a second tape area folded at a certain angle from the first tape area and having a third length.

2. The flexible flat cable of claim 1, further comprising a connecting member through which the part of the conductive wire portion is exposed between one end of the cover film and one end of the base film,
wherein the second tape area is folded at the one end of the cover film where the connecting member is located.

3. The flexible flat cable of claim 1, wherein a length of the second tape area is in a range of 3 cm to 10 cm.

4. The flexible flat cable of claim 1, wherein the first conductive tape comprises:
a conductive material layer extending in the first direction; and
a protective layer on a surface of the conductive material layer.

5. The flexible flat cable of claim 4, wherein the conductive material layer comprises at least one of aluminum, an aluminum alloy, copper, silver, or gold.

6. The flexible flat cable of claim 4, wherein a first surface of the conductive material layer located in the first tape area faces the cover film, and
a second surface of the conductive material layer in the second tape area is exposed to an outside.

7. The flexible flat cable of claim 1, wherein each of the base film and the cover film comprises an insulating material.

8. The flexible flat cable of claim 1, wherein the second tape area contacts a first ground portion provided on a first component and contacts a second ground portion provided on a third component.

9. The flexible flat cable of claim 8, wherein the first component comprises a printed circuit board, and
wherein the third component comprises at least one of a frame portion, a heat dissipation portion, a metal case, or a surface-mounted device gasket.

10. The flexible flat cable of claim 1, further comprising a second conductive tape comprising a third tape area on a second surface of the base film so as to overlap the base film along the first direction and a fourth tape area extending from the third tape area in the first direction so as not to overlap the base film.

11. The flexible flat cable of claim 10, wherein a length of the third tape area is in a range of 3 cm to 10 cm.

12. The flexible flat cable of claim 10, wherein the second conductive tape comprises:
a conductive material layer extending in the first direction; and
a protective layer on a surface of the conductive material layer.

13. The flexible flat cable of claim 12, wherein a first surface of the conductive material layer in the third tape area faces the base film, and
wherein a second surface of the conductive material layer in the fourth tape area is exposed to an outside.

14. The flexible flat cable of claim 1, further comprising a support tape on a second surface of the base film and comprising a material having an elastic force.

15. The flexible flat cable of claim 1, wherein the conductive wire portion comprises a plurality of conductive wire portions,
wherein the plurality of conductive wire portions comprise a first conductive wire portion configured to transmit a signal and a second conductive wire portion configured to transmit an operating voltage, and
wherein the plurality of conductive wire portions do not comprise a ground conductive wire portion.

16. The flexible flat cable of claim 10, further comprising a connecting member through which the part of the conductive wire portion is exposed between one end of the cover film and one end of the base film,
wherein the second tape area is folded at the one end of the cover film where the connecting member is located.

17. The flexible flat cable of claim 10, wherein a length of the second tape area is in a range of 3 cm to 10 cm.

18. The flexible flat cable of claim 10, wherein the first conductive tape comprises:
a conductive material layer extending in the first direction; and
a protective layer on a surface of the conductive material layer.

19. The flexible flat cable of claim 18, wherein the conductive material layer comprises at least one of aluminum, an aluminum alloy, copper, silver, or gold.

20. The flexible flat cable of claim 18, wherein a first surface of the conductive material layer located in the first tape area faces the cover film, and
a second surface of the conductive material layer in the second tape area is exposed to an outside.
